(19) United States
(12) Patent Application Publication
(10) Pub. No.: US 2015/0342069 A1
(43) Pub. Date: Nov. 26, 2015

(54) HOUSING FOR ELECTRONIC DEVICES

(71) Applicant: Chee Seng Foong, Sungai Buloh (MY)

(72) Inventor: Chee Seng Foong, Sungai Buloh (MY)

(73) Assignee: Freescale Semiconductor, Inc., Austin, TX (US)

(21) Appl. No.: 14/281,917

(22) Filed: May 20, 2014

(51) Int. Cl. H05K 5/02; H05K 3/34; H05K 5/00; H05K 3/10; H05K 1/18; H05K 3/30; H05K 3/00

(52) U.S. Cl. CPC H05K 5/0247; H05K 3/303; H05K 3/341; H05K 3/0061; H05K 3/102; H05K 3/0014; H05K 3/0044; H05K 1/181; H05K 5/0086

(57) ABSTRACT

Traces are formed and electronic components are mounted on an interior surface of a housing of an electronic device. Various methods are disclosed for integrating the housing with the electronic components including vacuum molding, metal forming, injection molding, and 3D printing of traces. The housing may be used to save space and reduce the size of the electronic devices as well as reduce assembly times.

### BACKGROUND OF THE INVENTION

The present invention relates generally to electronic devices and, more particularly, to electronic devices having electronic components that are integral with a housing of the components.

A typical electronic device, such as a handheld consumer device, like a cell phone or personal digital assistant, has one or more discrete printed circuit boards (PCBs) mounted within a plastic or metal housing, where a number of discrete electronic components are mounted on each PCB and interconnected by metal traces of the PCB. This means that the housing has to be sized to accommodate the installation of the circuit boards and their mounted electronic components. Usually the PCB will be sized to fit the housing, but if there are additional components required, additional PCBs may be needed, which will require larger housings.

### BRIEF DESCRIPTION OF THE DRAWINGS

Embodiments of the present invention are illustrated by way of example and are not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIGS. 1A-1E show cross-sectional side views of different stages in the manufacturing of a housing portion of an electronic device using vacuum forming, in accordance with an embodiment of the invention;

FIG. 2A is a cross-sectional side views of a stage in the manufacturing of a housing portion of an electronic device using a mold cavity for injection molding in accordance with an embodiment of the invention;

FIG. 2B shows an exploded view of the configuration shown in FIG. 2A;

FIGS. 2C-2D show cross-sectional side views of additional different stages in the manufacturing of a housing portion of an electronic device using a mold cavity for injection molding in accordance with an embodiment of the invention;

FIGS. 3A-3E show cross-sectional side views of different stages in the manufacturing of a housing portion of an electronic device using metal forming in accordance with an embodiment of the invention;

FIG. 4A is a cross-sectional side view of a stage in the manufacturing of a housing portion of an electronic device using 3D printing in accordance with an embodiment of the invention;

FIG. 4B shows a perspective view of the traces formed on a substrate in accordance with an embodiment of the invention;

FIG. 4C is a cross-sectional side view of another stage in the manufacturing of a housing portion of an electronic device using 3D printing in accordance with an embodiment of the invention; and

FIGS. 5A-5E show cross-sectional side views of different stages in the manufacturing of a housing of an electronic device using 3D printing with upside-down mounted electronic components, in accordance with another embodiment of the invention.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. Embodiments of the present invention may be embodied in many alternative forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “has,” “having,” “includes,” and/or “including” specify the presence of stated features, steps, or components, but do not preclude the presence or addition of one or more other features, steps, or components. It also should be noted that, in some alternative implementations, the functions/acts noted may occur out of the order noted in the figures. For example, two figures shown in succession may in fact be executed substantially concurrently or may sometimes be executed in the reverse order, depending upon the functionality/acts involved.

In accordance with embodiments of this invention, electronic devices having circuitry and electronic components embedded within and forming a portion of the interior surface of the housing for the electronic devices are disclosed. Having a housing portion formed with the circuitry and electronic components embedded within and forming a portion of the interior surface reduces the space needed to house the electronics of the electronic devices. This permits the electronic device to be smaller and makes assembly more efficient by reducing the number of steps needed to assemble the electronic device.

One embodiment in accordance with the invention may be a method of manufacturing an electronic device. A housing having an interior surface and an exterior surface is formed, wherein a portion of the interior surface has traces formed thereon. The electronic components are mounted on the portion of the interior surface so that the electronic components are electrically connected to the traces.

Another embodiment in accordance with the invention may be a method of manufacturing an electronic device. Electronic components are mounted upside-down on a substrate, conductive powder is placed over the electronic components, and selected portions of the conductive material are sintered or melted to form the traces, wherein the traces electrically connect the electronic components.

Still yet another embodiment in accordance with the invention may be an electronic device having housing, wherein the housing has an interior surface and an exterior surface. A flexible printed circuit board (PCB) forms a portion of the interior surface of the housing, wherein the flexible PCB has traces formed thereon. Electronic components are mounted on and electrically connected to the traces, wherein the housing and the PCB are shaped one to the other.

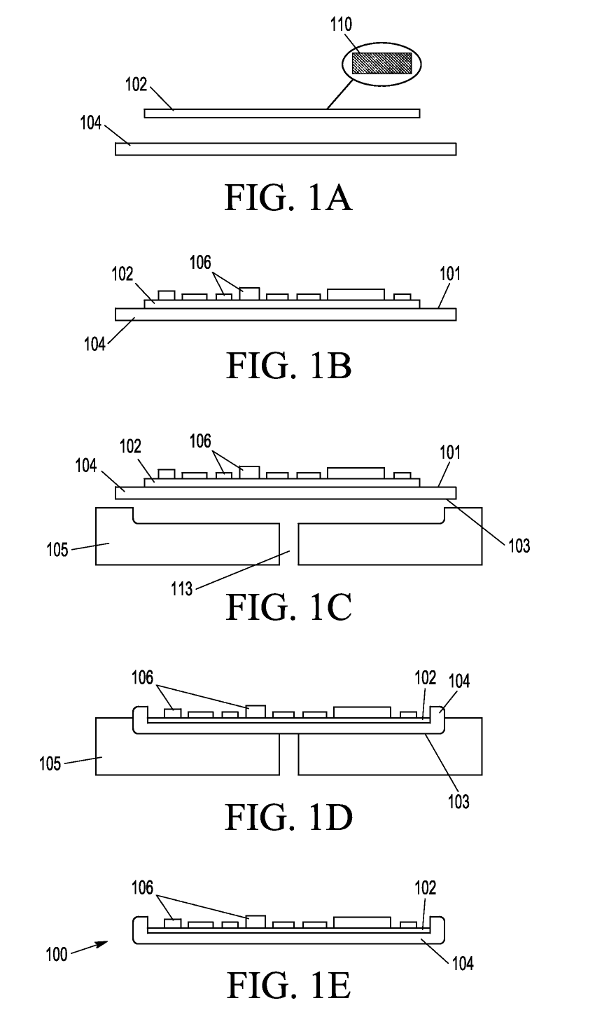

Turning now to FIGS. 1A-1E, vacuum molding a housing portion is shown in accordance with an embodiment of the invention. In the vacuum molding process, a plastic substrate is heated and placed within a vacuum mold in order to form the housing portion. A flexible printed circuit board (PCB) film is used to provide the circuitry within an interior surface of the housing portion. Electronic components are electrically connected to the traces on the surface of the flexible PCB film. Electronic components are components that are used in the functioning of a fully assembled electrical device. For example, the electronic components may be, but are not limited to, integrated circuits, power sources, discharge devices, resistors, capacitors, transducers, antennas, switches, etc.

FIG. 1A shows flexible PCB film 102 being mounting onto a plastic substrate 104. Flexible PCB film 102 has traces 110 formed thereon as shown in the call out to FIG. 1A. Plastic substrate 104 will form a portion of the housing for the finished electronic device. The plastic substrate 104 may be any plastic material suitable for vacuum molding, for instance, thermoplastic or a thermoset material.

FIG. 1B shows the flexible PCB film 102 after being laminated onto the interior surface 101 of plastic substrate 104 and cured. After the flexible PCB film 102 is laminated and cured onto the interior surface 101 of the plastic substrate 104, the electronic components 106 are surface mounted to the flexible PCB film 102 and electrically connected.

FIG. 1C shows a vacuum mold 105. The sub-assembly of FIG. 1B is heated to a point where the plastic substrate 104 is able to be molded. The vacuum mold 105 applies a suction force via outlet 113 to pull the heated plastic substrate 104 down into the vacuum mold 105 to conform to the shape of the interior of the vacuum mold 105.

FIG. 1D shows the plastic substrate 104 after being subjected to the suction force and pulled down to form into the shape of the interior of the vacuum mold 105. After the molding process, the flexible PCB film 102 and the electronic components 106 form the interior portion of the device housing. The plastic substrate 104 is molded so that its exterior surface 103 forms the desired shape of the exterior of a housing portion. FIG. 1E shows the resulting finished housing portion 100 after being removed from the vacuum mold 105.

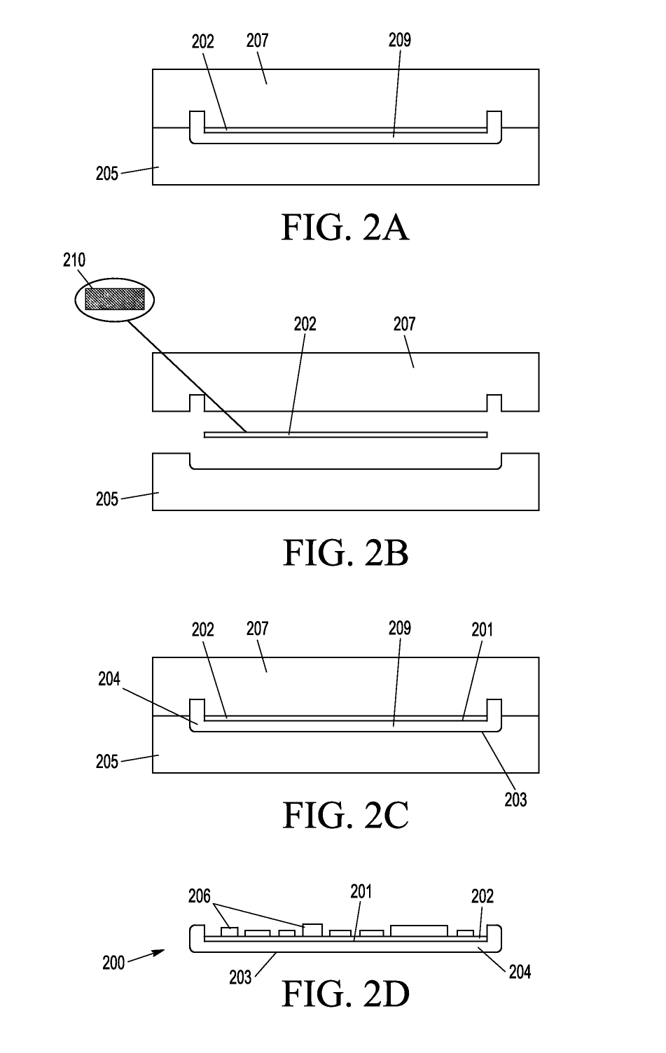

Turning now to FIGS. 2A-2D, injection molding a housing portion is shown in accordance with an embodiment of the invention. Elements in FIGS. 2A-2D are labeled in a similar manner to those referred to above with respect to FIGS. 1A-1E, where differences occurring with respect to elements and steps will be noted.

In FIGS. 2A-2D, instead of a vacuum mold, an injected mold is used. The injection mold has a top mold and a bottom mold that, when placed together, form a cavity. The cavity formed by the top and bottom molds is filled with a moldable substrate material and is sized and shaped to form a portion of the housing for an electronic device.

FIG. 2A shows top mold 207 and bottom mold 205 clamped down and forming cavity 209. The clamping down of top mold 207 and bottom mold 205 further secures the placement of flexible PCB film 202 within the cavity 209 via the use of vacuum holes (not shown) within the top mold 207 and readies the mold for the receipt of a moldable substrate material.

FIG. 2B is an exploded view of the configuration shown in FIG. 2A. FIG. 2B shows flexible PCB film 202 placed between the top mold 207 and the bottom mold 205 of an injection mold. Flexible PCB film 202 has traces 210 formed thereon as shown in the call out to FIG. 2B. Traces 210 are on the side of film 202 facing towards the top mold 207.

Now referring to FIG. 2C, moldable substrate material 204 is injected into and fills cavity 209 via one or more openings (not shown in the figures) in the injection mold, thereby surrounding and embedding flexible PCB film 202. The moldable substrate material 204 does not cover the traces located on the side of the flexible PCB film 202 facing the top mold 207. The traces need to be free of moldable substrate material 204 to enable subsequent mounting of electronic components 206.

Substrate material 204 may be thermoset material or other suitable material that is capable of being injection molded. Moldable substrate material 204 undergoes a chemical curing process to solidify forming an interior surface 201 and an exterior surface 203. The solidified substrate material 204 is released with the flexible PCB film 202 embedded and formed within the interior surface 201. The flexible PCB film 202 is capable of having electronic components mounted thereon and electrically connected to its circuitry traces.

FIG. 2D shows the electronic components 206 mounted on the flexible PCB film 202 and having the circuitry traces electrically connected to the electronic components 206. The substrate material 204 forms a finished housing portion 200 of an electronic device.

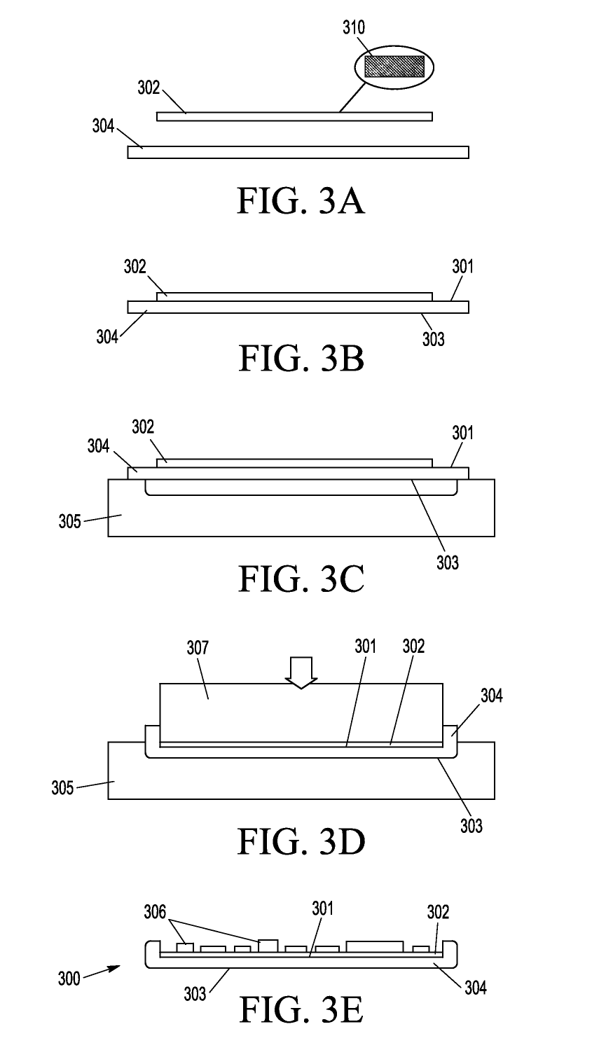

Now turning to FIGS. 3A-3D, metal forming a housing portion is shown in accordance with an embodiment of the invention. Elements in FIGS. 3A-3D are labeled in a similar manner to those referred to in the figures discussed above, where differences occurring with respect to elements and steps will be noted.

FIGS. 3A-3D show a metal-forming process in which a flexible PCB film is secured to the surface of a metal substrate, and the metal substrate is then punched to form the desired shape of the housing portion.

FIG. 3A shows a flexible PCB film 302 being placed onto a metal substrate 304 having an interior surface 301 and an exterior surface 303, as shown in FIG. 3B. Flexible PCB film 302 has traces 310 formed thereon as shown in the call out to FIG. 3A. The metal substrate 304 may be any suitable type of metal material 304 that may be able to form a housing for an electronic device, for example, aluminum. The flexible PCB film 302 is laminated and cured onto the interior surface 303 of the metal substrate 304. The traces 310 are located on the side of the flexible PCB film 302 that will face the punch mold to enable subsequent mounting of electronic components 206.

In FIG. 3C, the sub-assembly of the metal substrate 304 and flexible PCB film 302 are placed over the cavity of the punch mold 305 having the desired shape for the finished housing portion. The metal substrate 304 may be heated to a point where it is malleable within the punch mold.

FIG. 3D shows punch mold top (i.e., forge press) 307 pushing down on the interior surface 301 of the metal substrate 304. During the punch process, portions of the metal substrate 304 are molded so that the interior surface 301 having the flexible PCB film 302 forms a portion of the interior of a housing. The exterior surface 303 of the metal substrate 304 is molded in order to form the desired shape of the exterior of the housing portion.

In FIG. 3E, the electronic components 306 are mounted onto the flexible PCB film 302 and electrically connected to the traces formed thereon. The flexible PCB film 302, electronic components 306, and metal substrate 304 form the finished housing portion 300 of an electronic device.

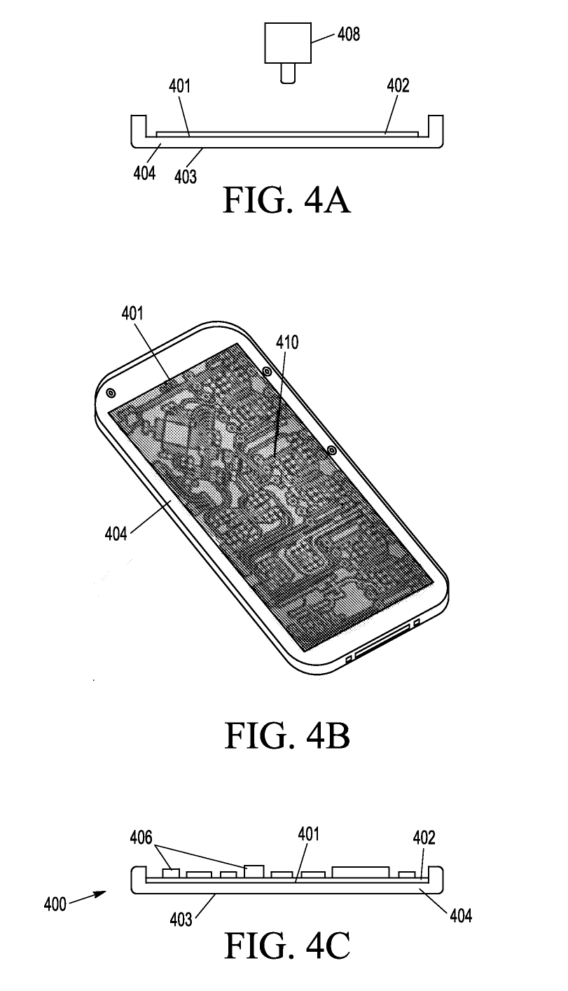

FIGS. 4A-4C show the forming of a housing portion using 3D printing of traces. Elements in FIGS. 4A and 4B are labeled in a similar manner to those referred to in the figures above, where differences occurring with respect to elements and steps will be noted.

In FIGS. 4A-4C, the 3D printing of traces involves placing a conductive material on a surface and using the conductive material to either form traces for circuitry or have traces for circuitry formed thereon. Lasers are used to heat (e.g., sinter or melt) the conductive material to form the traces.

FIG. 4A shows a pre-molded substrate 404 having an interior surface 401 and an exterior surface 403 and formed from a plastic or metal material. Placed on the interior surface 401 of the substrate 404 is a conductive material 402. The conductive material 402 may be a conductive ink or powder, such as a powder of copper, titanium alloy, aluminum alloy, nickel alloy, or cobalt chrome alloy.

A laser 408 directly forms traces (not shown) on the interior surface 401 of the substrate 404 by selectively sintering or melting the conductive material 402.

FIG. 4B is a perspective view of the substrate 404 with the traces 410 formed on the interior surface 401. As shown in FIG. 4C, after the traces are formed, electronic components 406 are mounted to the interior surface 401 and are electrically connected to the traces. The substrate 404 with its traces formed directly thereon and the electrically connected electronic components 406 form the finished housing portion 400 of an electronic device.

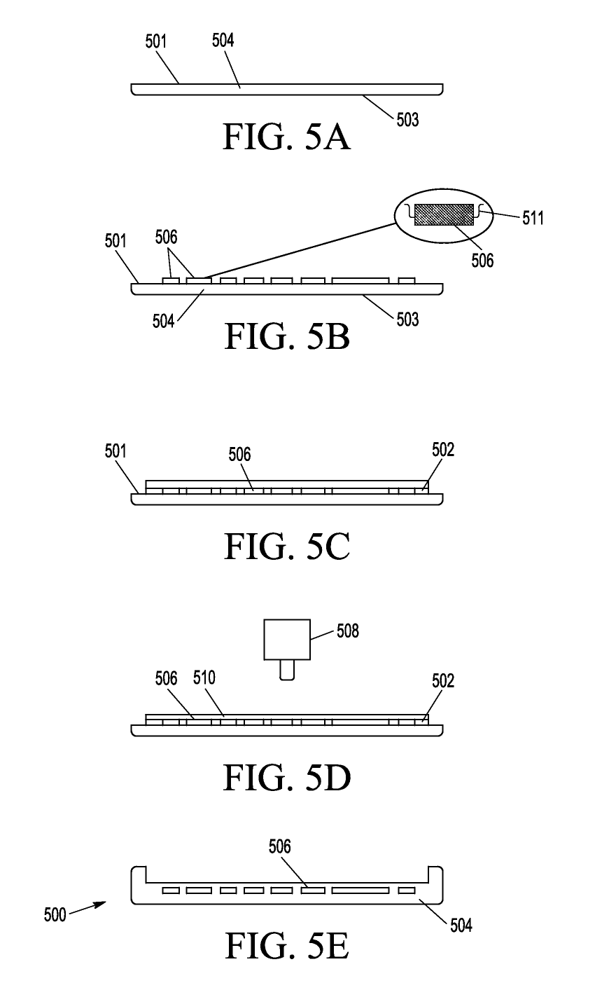

FIGS. 5A-5E show another technique for forming a housing portion using 3D printing of traces. In this embodiment, upside-down electronic components are used in the formation of the housing portion. Elements in FIGS. 5A-5E are labeled in a similar manner to those referred to above with respect figures above, where differences occurring with respect to elements and steps will be noted.

In the 3D printing method discussed in FIGS. 5A-5E, electronic components are mounted upside-down on the interior surface of what will be the finished housing portion. [Conductive material is then placed thereon and traces are formed to electrically connect the upside-down mounted electronic components.

FIG. 5A shows a substrate 504 having an interior surface 501 and exterior surface 503. In FIG. 5B, the interior surface 501 of the substrate 504 has electronic components 506 mounted thereon in such a manner that they are upside-down with respect to the interior surface 501. By upside-down, it is meant that the I/O leads 511 are oriented so that they are facing up with respect to the portions of the drawings as illustrated in the called out portion of FIG. 5B.

FIG. 5C shows the interior surface 501 and the electronic components 506 after the electronic components 506 are covered in plastic material 502 (cured and solidified) to hold them in place and also to provide a surface on which conductive material may be placed.

FIG. 5D shows a laser 508 positioned above the substrate 504 after conductive material 510 is applied over the plastic material 502 that covers the electronic components 506 prior to forming the traces. The laser 508 is used to form traces (not shown) by sintering or melting the conductive material 510. The traces are formed so that they electrically connect the I/O leads 511 of the electronic components 506. FIG. 5E shows the finished housing portion 500 of an electronic device formed by the substrate 504 with its traces and upside-down electronic components 506.

The above-disclosed methods for forming the traces and mounting the electronic components within an interior portion of the housing permit the reduction of the housing size needed for the electronic device. Reducing the size of the housing permits reduction in the volume and weight of the electronic device. This can also allow for more electronic components to be placed with the previously used housing space. Furthermore, having the circuitry and electronic components forming part of the interior surface may provide an opportunity to form fully functioning electronic devices of various shapes and sizes that were not possible when accommodation was needed within the housing for the various components.

The above-disclosed methods may reduce the cost of assembly. The production methods may involve fewer steps since additional steps are needed for the prior-art assembly and subsequent installation of distinct PCBs. Since the circuitry and electronic components are mounted onto the interior surface of the housing, these separate steps might not be needed.

The above-disclosed methods may be useful for forming portions of housing for such devices as mobile phones, cameras, computers, display systems, and home appliances. Additionally, portions of automobiles may also be assembled using the methods contemplated in the disclosures.

Although the invention has been described using relative terms such as “front,” “back,” “top,” “bottom,” “over,” “above,” “under” and the like in the description and in the claims, such terms are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to specific embodiments are not intended to be construed as a critical, required, or essential feature or element of any or all the claims.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. A method of manufacturing an electronic device, the method comprising:
(a) forming a housing having an interior surface and an exterior surface, wherein a portion of the interior surface has traces formed thereon; and
(b) mounting electronic components on the portion of the interior surface so that the electronic components are electrically connected to the traces.

2. An electronic device formed by the method of manufacture of claim 1.

3. The method of claim 1, wherein:
the housing comprises a substrate and a flexible printed circuit board (PCB) film mounted on the substrate, wherein the flexible PCB film forms the portion of the interior surface;
the flexible PCB film has the traces formed thereon; and
step (b) comprises mounting the electronic components on the flexible PCB film so that the electronic components are electrically connected to the traces of the flexible PCB film.

4. The method of claim 3, wherein:
the substrate is made of plastic; and
further comprising vacuum molding the plastic substrate to form a portion of the housing for the electronic device.

5. The method of claim 4, wherein the vacuum molding is performed after step (b).

6. An electronic device formed by the method of manufacture of claim 5.

7. The method of claim 3, wherein step (a) comprises:
placing the flexible PCB film in a mold; and
injection molding substrate material into the mold to form a portion of the housing for the electronic device, wherein the portion comprises the substrate with the flexible PCB film mounted thereon.

8. An electronic device formed by the method of manufacture of claim 7.

9. The method of claim 3, wherein:
the substrate is made of metal; and
step (a) comprises:
laminating the flexible PCB film onto the metal substrate to form the housing material; and
punching the housing material to form a portion of the housing for the electronic device, the portion comprising the substrate with the flexible PCB film mounted thereon.

10. An electronic device formed by the method of manufacture of claim 9.

11. The method of claim 1, wherein step (a) comprises:
applying conductive material to a substrate; and
sintering or melting selected portions of the conductive material to form the traces directly on the substrate.

12. An electronic device formed by the method of manufacture of claim 11.

13. A method of manufacturing an electronic device, the method comprising:
mounting electronic components upside-down on a substrate;
placing conductive material over the electronic components; and
sintering or melting selected portions of the conductive material to form traces that electrically connect the electronic components.

14. The method of claim 13, further comprising:
forming a housing from the substrate, wherein the housing has an interior surface and an exterior surface and the electronic components are mounted on a portion of the interior surface.

15. An electronic device formed by the method of claim 14.

16. An electronic device, comprising:
a housing having an interior surface and an exterior surface;
a flexible printed circuit board (PCB) forming a portion of the interior surface of the housing, wherein the flexible PCB has traces formed thereon; and
electronic components mounted on and electrically connected to the traces,
wherein the housing and the PCB are shaped one to the other.

17. The electronic device of claim 16, wherein the housing and the PCB are shaped one to the other via vacuum.

18. The electronic device of claim 17, wherein the housing and the PCB are shaped one to the other via punching.

19. The electronic device of claim 17, wherein the PCB comprises a film.

20. The electronic device of claim 19, wherein the film is attached to the housing with an adhesive.
